(19) United States
(12) Patent Application Publication
(10) Pub. No.: US 2025/0331168 A1
(43) Pub. Date: Oct. 23, 2025

(54) SEMICONDUCTOR DEVICE HAVING INSULATING STRUCTURE

(71) Applicant: Samsung Electronics Co., Ltd., Suwon-si (KR)

(72) Inventors: Hosang Lee, Suwon-si (KR); Sangsuk Han, Suwon-si (KR); Taejin Park, Suwon-si (KR); Euijoong Shin, Suwon-si (KR); Ilyoung Yoon, Suwon-si (KR); Hao Cui, Suwon-si (KR)

(21) Appl. No.: 19/053,751

(22) Filed: Feb. 14, 2025

(30) Foreign Application Priority Data
Apr. 23, 2024 (KR) 10-2024-0053810

(51) Int. Cl. H10B 12/00; H10D 64/27

(52) U.S. Cl. CPC H10B 12/482; H10B 12/315; H10B 12/488; H10D 64/513

(57) ABSTRACT

A semiconductor device includes a bit line structure, a back gate electrode and a word line on the bit line structure, an active pattern between the back gate electrode and the word line, on the bit line structure, the active pattern extending in a vertical direction, a back gate dielectric layer between the back gate electrode and the active pattern, the back gate dielectric layer on a side surface and a lower surface of the back gate electrode, and a first insulating structure between the back gate dielectric layer and the bit line structure. The first insulating structure includes a first stopper in contact with the back gate dielectric layer and the bit line structure. The back gate dielectric layer is spaced apart from the bit line structure by the first stopper in the vertical direction.

### CROSS-REFERENCE TO RELATED APPLICATION(S)

This application claims benefit of priority under 35 U.S.C. § 119 to Korean Patent Application No. 10-2024-0053810 filed on Apr. 23, 2024 in the Korean Intellectual Property Office, the disclosure of which is incorporated herein by reference in its entirety.

### BACKGROUND

The present inventive concept relates generally to a semiconductor device having an insulating structure.

As demand for implementation of high performance, high speed, and/or multi-functionalization of semiconductor devices increases, a degree of integration of semiconductor devices has been increasing. In manufacturing semiconductor devices having a fine pattern corresponding to the trend for a high degree of integration of semiconductor devices, it is necessary to implement patterns having a fine width or a fine separation distance.

### SUMMARY

An aspect of the present inventive concept provides a semiconductor device having an insulating structure including a stopper.

According to an aspect of the present inventive concept, there is provided a semiconductor device including a bit line structure, a back gate electrode and a word line on the bit line structure, an active pattern between the back gate electrode and the word line, on the bit line structure, the active pattern extending in a vertical direction, a back gate dielectric layer between the back gate electrode and the active pattern, the back gate dielectric layer covering (i.e., on) a side surface and a lower surface of the back gate electrode, and a first insulating structure between the back gate dielectric layer and the bit line structure. The first insulating structure may include a first stopper in contact with the back gate dielectric layer and the bit line structure. The back gate dielectric layer may be spaced apart from the bit line structure in a vertical direction.

According to another aspect of the present inventive concept, there is provided a semiconductor device including a bit line structure, a back gate electrode and a word line on the bit line structure, an active pattern between the back gate electrode and the word line, on the bit line structure, the active pattern extending in a vertical direction, a back gate dielectric layer between the back gate electrode and the active pattern, the back gate dielectric layer covering a side surface and a lower surface of the back gate electrode, a gate dielectric layer between the word line and the active pattern, the gate dielectric layer covering a side surface and a lower surface of the word line, a first insulating structure between the back gate dielectric layer and the bit line structure, and a second insulating structure between the gate dielectric layer and the bit line structure. The active pattern may include a first portion and a second portion on the first portion. The first portion of the active pattern may be in contact with the first insulating structure and the second insulating structure. The second portion of the active pattern may be in contact with the back gate dielectric layer and the gate dielectric layer.

According to another aspect of the present inventive concept, there is provided a semiconductor device including a bit line structure, a back gate electrode and a word line on the bit line structure, an active pattern between the back gate electrode and the word line, on the bit line structure, the active pattern extending in a vertical direction, a contact structure on the active pattern, an information storage structure on the contact structure, a back gate dielectric layer between the back gate electrode and the active pattern, the back gate dielectric layer covering a side surface and a lower surface of the back gate electrode, the back gate dielectric layer in contact with a side surface of the active pattern, a gate dielectric layer between the word line and the active pattern, the gate dielectric layer covering a side surface and a lower surface of the word line, the gate dielectric layer in contact with the side surface of the active pattern, a first insulating structure in contact with a lower surface of the back gate dielectric layer and an upper surface of the bit line structure, and a second insulating structure in contact with a lower surface of the gate dielectric layer and the upper surface of the bit line structure. The first insulating structure may include a first stopper in contact with the back gate dielectric layer and the bit line structure. The back gate dielectric layer may be spaced apart from the bit line structure in a vertical direction.

### BRIEF DESCRIPTION OF DRAWINGS

The above and other aspects, features, and advantages of the present inventive concept will be more clearly understood from the following detailed description, taken in conjunction with the accompanying drawings, wherein like reference numerals (when used) indicate corresponding elements throughout the several views, and in which:

FIG. 1 is a schematic plan view of a semiconductor device according to an example embodiment;

FIG. 2 is a schematic vertical cross-sectional view of the semiconductor device illustrated in FIG. 1, taken along line I-I′;

FIG. 3 is a partially enlarged view of the semiconductor device illustrated in FIG. 2;

FIGS. 4 to 9 are schematic vertical cross-sectional views of semiconductor devices according to example embodiments;

FIG. 10 is a flowchart of a method for manufacturing a semiconductor device according to an example embodiment;

FIGS. 11 to 25 are schematic vertical cross-sectional views of sequential intermediate processes in a method of manufacturing a semiconductor device according to an example embodiment;

FIG. 26 is a flowchart of a method of manufacturing a semiconductor device according to an example embodiment;

FIGS. 27 to 32 are schematic vertical cross-sectional views of sequential intermediate processes in a method of manufacturing a semiconductor device according to an example embodiment;

FIG. 33 is a flowchart of a method of manufacturing a semiconductor device according to an example embodiment; and

FIGS. 34 to 38 are schematic vertical cross-sectional views of sequential intermediate processes in a method of manufacturing a semiconductor device according to an example embodiment.

### DETAILED DESCRIPTION

Hereinafter, preferred example embodiments of the present inventive concept will be described with reference to the accompanying drawings.

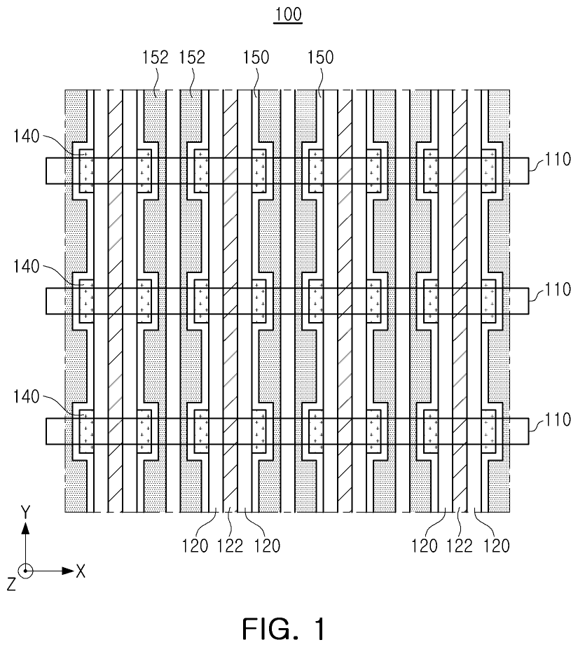

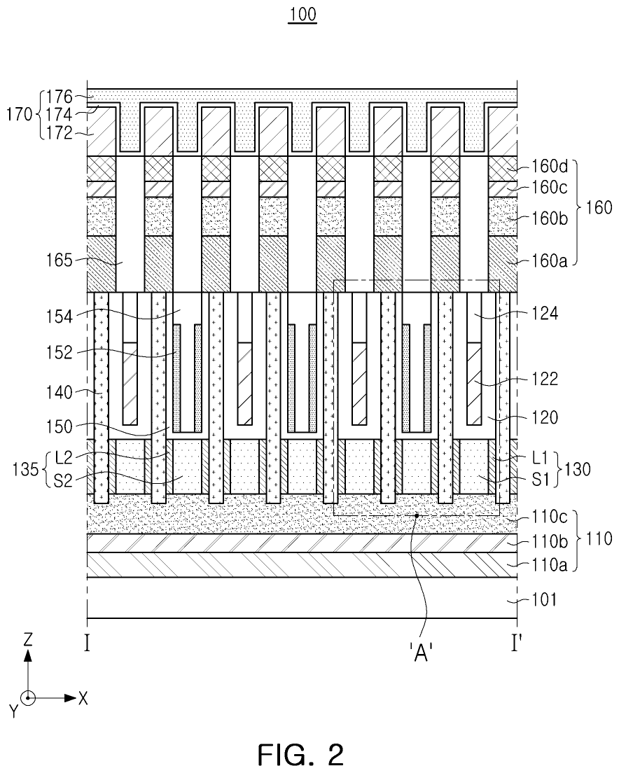

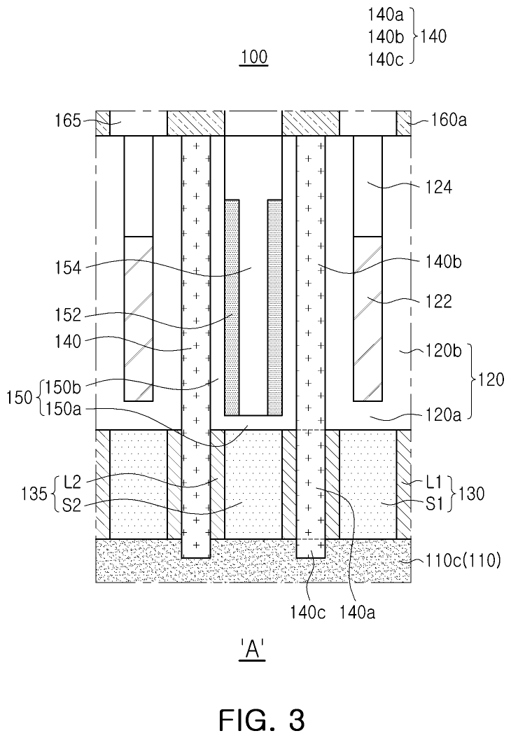

FIG. 1 is a schematic plan view of a semiconductor device according to an example embodiment. FIG. 2 is a schematic vertical cross-sectional view of the semiconductor device illustrated in FIG. 1, taken along line I-I′. FIG. 3 is a partially enlarged view of the semiconductor device illustrated in FIG. 2.

Referring to FIGS. 1 to 3, a semiconductor device 100 according to an example embodiment of the present inventive concept may include a lower insulating layer 101, a bit line structure 110, a back gate electrode 122, a first insulating structure 130, a second insulating structure 135, an active pattern 140, a word line 152, a contact pattern 160, and an information storage structure 170.

The semiconductor device 100 may include a vertical channel transistor including an active pattern 140, a bit line structure 110 electrically connected to the active pattern 140, and word lines 152 disposed on at least one side surface of the active pattern 140. The term “vertical” is intended to refer to an extension or orientation in a direction perpendicular to an upper surface of the lower insulating layer 101 (or other substrate), which is a Z-direction.

The semiconductor device 100 may be applied to, for example, a cell array of a dynamic random access memory (DRAM), but the present inventive concept is not limited thereto.

The lower insulating layer 101 may include an insulating material such as silicon oxide, silicon nitride, silicon oxynitride (SiON), or silicon carbonitride (SiCN).

The bit line structure 110 may extend in an X-direction, parallel to the upper surface of the lower insulating layer 101, on the lower insulating layer 101. In an example embodiment, the bit line structure 110 may be buried in the lower insulating layer 101. The bit line structure 110 may be electrically connected to the active pattern 140. The term “connected” (or “connecting,” or like terms, such as “contact” or “contacting”), as may be used herein, is intended to refer to a physical and/or electrical connection between two or more elements, and may include other intervening elements. As used herein, the term “and/or” includes any and all combinations of one or more of the associated listed items. A plurality of bit line structures 110 may be provided, and the plurality of bit line structures 110 may be spaced apart from each other in a Y-direction, parallel to the upper surface of the lower insulating layer 101 and intersecting the X-direction, and may extend to be parallel to each other.

The bit line structure 110 may include doped polysilicon, a metal, a conductive metal nitride, a metal-semiconductor compound, a conductive metal oxide, graphene, carbon nanotubes, or combinations thereof. For example, at least one of the bit line structures 110 may be formed of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOₓ, RuOₓ, graphene, carbon nanotubes, or combinations thereof. In an example embodiment, the bit line structure 110 may include a first conductive pattern 110a, a second conductive pattern 110b, and a third conductive pattern 110c, sequentially stacked on the lower insulating layer 101 in the vertical direction. The first conductive pattern 110a may include, for example, a metal material such as titanium (Ti), tantalum (Ta), tungsten (W), and aluminum (Al), the second conductive pattern 110b may include, for example, a metal nitride such as titanium nitride (TiN) or a silicide material such as titanium silicide (TiSi), and the third conductive pattern 110c may include a semiconductor material such as polycrystalline silicon. The third conductive pattern 110c may be a layer doped with impurities. However, depending on example embodiments, a material of layers of the bit line structure 110, the number of the layers, and a cross-sectional thickness of each of the layers included in the bit line structure 110 may be changed in various manners.

The semiconductor device 100 may further include a back gate dielectric layer 120 and a back gate capping layer 124.

The back gate electrodes 122 may intersect the bit line structures 110. For example, the back gate electrodes 122 may extend in the Y-direction, and may be spaced apart from each other in the X-direction.

The back gate electrode 122 may serve to remove charges trapped in the active pattern 140. The active pattern 140 may be a floating body, and the back gate electrode 122 may be a structure to complement the floating active pattern 140 to prevent or minimize degradation in performance of the semiconductor device 100 caused by a floating body effect of the active pattern 140.

The back gate electrode 122 may include doped polysilicon, a metal, a conductive metal nitride, a metal-semiconductor compound, a conductive metal oxide, graphene, carbon nanotubes, or combinations thereof. For example, the back gate electrode 122 may be formed of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOₓ, RuOₓ, graphene, carbon nanotubes, or combinations thereof, but the present inventive concept is not limited thereto. The back gate electrode 122 may be formed of a single layer or multiple layers, formed of the above-described materials.

The back gate dielectric layers 120 may cover side surfaces and lower surfaces of the back gate electrodes 135, and may extend in the Y-direction. The term “cover” (or “covering,” “covers,” or like terms), as may be used herein, is intended to broadly refer to an element, structure or layer that is on or over another element, structure or layer, either directly or with one or more other intervening elements, structures or layers therebetween. The back gate dielectric layer 120 may have a U-shape, in cross-sectional view. For example, the back gate dielectric layer 120 may a horizontal portion 120a covering a lower surface of the back gate electrode 122, the horizontal portion 120a extending in the vertical direction, and vertical portions 120b upwardly extending (in the Z-direction) from an upper surface of the horizontal portion 120a. The vertical portions 120b may respectively cover side surfaces of the back gate electrode 122.

An upper surface of the vertical portion 120b of the back gate dielectric layer 120 may be positioned on a level, higher than that of an upper surface of the back gate electrode 122, and a lower surface of the horizontal portion 120a of the back gate dielectric layer 120 may be positioned on a level, lower than that of the lower surface of the back gate electrode 122. The upper surface of the vertical portion 120b of the back gate dielectric layer 120 may be coplanar with an upper surface of the active pattern 140, relative to the upper surface of the lower insulating layer 101 as a reference layer. The back gate dielectric layer 120 may not be in contact with the bit line structure 110, and may be spaced apart from the bit line structure 110. For example, the first insulating structure 130 may be disposed between the bit line structure 110 and the back gate dielectric layer 120. Each of the back gate dielectric layers 120 may include at least one of silicon oxide and a high-κ dielectric.

The back gate capping layer 124 may be disposed on the back gate electrode 122. An upper surface of the back gate capping layer 124 may be coplanar with an upper surface of the back gate dielectric layer 120, relative to the upper surface of the lower insulating layer 101. The back gate dielectric layer 120 may cover side surfaces of the back gate capping layer 124.

The back gate capping layer 124 may include silicon oxide, silicon nitride, silicon oxynitride, silicon carbonitride, a low-κ dielectric, or combinations thereof.

The first insulating structure 130 may be disposed between the bit line structure 110 and the back gate dielectric layer 120. A lower surface and an upper surface of the first insulating structure 130 may be in contact with an upper surface of the third conductive pattern 110c of the bit line structure 110 and a lower surface of the back gate dielectric layer 120, respectively. The first insulating structure 130 may also be disposed between active patterns 140, adjacent to each other in the X-direction. Side surfaces of the first insulating structure 130 may be in contact with the active patterns 140. In an example embodiment, the lower surface of the first insulating structure 130 may be positioned on a level, higher than that of lower surfaces of the active patterns 140.

In an example embodiment, the first insulating structure 130 may include first liners L1 and a first stopper layer S1. The first liners L1 may be disposed on opposite side surfaces of the first stopper layer S1. For example, the first liners L1 may cover the side surfaces of the first stopper layer S1 and the side surfaces of the active patterns 140, respectively. The first liners L1 and the first stopper layer S1 may be in contact with the horizontal portion 120a of the back gate dielectric layer 120. Upper surfaces and lower surfaces of the first liners L1 may be coplanar with upper surfaces and lower surfaces of the first stopper layer S1, but the present inventive concept is not limited thereto. In an example embodiment, the lower surfaces of the first liners L1 and the first stopper layer S1 may be disposed on a level, higher than that of the lower surface of the active pattern 140, relative to the upper surface of the lower insulating layer 101 as a reference.

The first liners L1 may include at least one of silicon oxide, silicon oxynitride, and silicon oxycarbide. The first stopper layer S1 may include silicon oxide.

The active pattern 140 may be disposed on the bit line structure 110, and may extend in the vertical direction (Z-direction). In plan view, the active patterns 140 may be disposed on opposite side surfaces of the back gate electrodes 122. The active patterns 140 may be spaced apart from each other in the X-direction and the Y-direction. The upper surface of the active pattern 140 may be coplanar with the upper surface of the back gate capping layer 124. The lower surface of the active pattern 140 may be in contact with the third conductive pattern 110c, and may be positioned on a level, lower than that of the lower surface of the back gate dielectric layer 120.

Each of the active patterns 140 may include a first source/drain region in contact with the bit line structure 110 and a second source/drain region connected to the contact pattern 160. In an example embodiment, the first and second source/drain regions may have an N-type conductivity type.

In an example embodiment, the active patterns 140 may include a single crystal semiconductor material. The single crystal semiconductor material may include a group IV semiconductor, a group III-V compound semiconductor, or a group II-VI compound semiconductor, for example, a single crystal semiconductor including at least one of silicon, silicon carbide, germanium, or silicon-germanium.

However, depending on example embodiments, the active patterns 140 may include at least one of a polycrystalline semiconductor material layer, an oxide semiconductor material layer such as indium gallium zinc oxide (IGZO), or a two-dimensional material layer such as MoS₂.

The oxide semiconductor layer may be indium gallium zinc oxide (IGZO). However, example embodiments are not limited thereto. For example, the oxide semiconductor layer may include at least one of indium tungsten oxide (IWO), indium tin gallium oxide (ITGO), indium aluminum zinc oxide (IAGO), indium gallium oxide (IGO), indium tin zinc oxide (ITZO), zinc tin oxide (ZTO), indium zinc oxide (IZO), ZnO, indium gallium silicon oxide (IGSO), indium oxide (InO), tin oxide (SnO), titanium oxide (TiO), zinc oxide (ZnON), manganese zinc oxide (MgZnO), indium zinc oxide (InZnO), indium gallium zinc oxide (InGaZnO), zirconium indium zinc oxide (ZrInZnO), hafnium indium zinc oxide (HfInZnO), tin indium zinc oxide (SnInZnO), aluminum tin indium zinc oxide (AlSnInZnO), silicon indium zinc oxide (SiInZnO), zinc tin oxide (ZnSnO), aluminum zinc tin oxide (AlZnSnO), gallium zinc tin oxide (GaZnSnO), zirconium zinc tin oxide (ZrZnSnO), and indium gallium silicon oxide (InGaSiO).

The two-dimensional material layer may include at least one of a transition metal dichalcogenide (TMD) material layer, a black phosphorous material layer, and a hexagonal boron-nitride (hBN) material layer, which may have semiconductor properties. For example, the 2D material layer may include at least one of BiOSe, Crl, WSe2, MoS2, TaS, WS, SnSe, ReS, β-SnTe, MnO, AsS, P (black), InSe, h-BN, GaSe, GaN, SrTiO, MXene, and a Janus 2D material, which may form a 2D material.

The word line 152 may be disposed on the bit line structure 110, and may be disposed on opposite side surfaces of the back gate electrodes 122. The word lines 152 may extend in the Y-direction, and may be spaced apart from each other in the X-direction. In plan view, the word line 152 may surround at least a portion of the active patterns 140, and the active patterns 140 may be disposed between the back gate dielectric layer 120 and the word line 152. The term “surround” (or “surrounds,” or like terms), as may be used herein, is intended to broadly refer to an element, structure or layer that extends around, envelops, encircles, or encloses another element, structure or layer on all sides, although breaks or gaps may also be present. Thus, for example, a material layer having voids or gaps therein may still “surround” another layer which it encircles.

The word line 152 may include doped polysilicon, a metal, a conductive metal nitride, a metal-semiconductor compound, a conductive metal oxide, graphene, carbon nanotubes, or combinations thereof. For example, the word line 152 may be formed of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOₓ, RuOₓ, graphene, carbon nanotubes, or combinations thereof, but the present inventive concept is not limited thereto. The word line 152 may be formed of a single layer or multiple layers, formed of one or more of the above-described materials.

The semiconductor device 100 may further include a gate dielectric layer 150 and a gate capping layer 154. In plan view, the gate dielectric layer 150 may be disposed between the word lines 152 and the active patterns 140, and may have a U-shape in cross-sectional view. For example, the gate dielectric layer 150 may include a horizontal portion 150a covering lower surfaces of the word lines 152, the horizontal portion 150a extending in a horizontal direction, and vertical portions 150b upwardly extending from an upper surface of the horizontal portion 150a. The vertical portions 150b may cover side surfaces of the word lines 152, respectively.

An upper surface of the vertical portion 150b of the gate dielectric layer 150 may be positioned on a level, higher than that of an upper surface of the word line 152, and a lower surface of the horizontal portion 150a of the gate dielectric layer 150 may be positioned on a level, higher than that of a lower surface of the word line 152. The upper surface of the vertical portion 150b of the gate dielectric layer 150 may be coplanar with the upper surface of the active pattern 140. The gate dielectric layer 150 may not be in contact with the bit line structure 110, and may be spaced apart from the bit line structure 110. For example, the second insulating structure 135 may be disposed between the bit line structure 110 and the back gate dielectric layer 120.

In an example, each of the gate dielectric layers 150 may be a tunnel dielectric layer, not including an information storage layer. For example, each of the gate dielectric layers 150 may include at least one of silicon oxide and a high-κ dielectric. The high-κ dielectric may include metal oxide or metal oxynitride. For example, the high-κ dielectric may be formed of HfO₂, HfSiO, HfSiON, HfTaO, HfTiO, HfZrO, ZrO₂, Al₂O₃, or combinations thereof, but the present inventive concept is not limited thereto. Each of the gate dielectric layers 150 may be formed of a single layer or multiple layers, formed of the above-described materials.

In another example, each of the gate dielectric layers 150 may include an information storage layer and a dielectric layer. For example, each of the gate dielectric layers 150 may have polarization properties depending on an electric field, and may include a ferroelectric layer that may have remnant polarization caused by a dipole even in the absence of an external electric field. Data may be recorded using such a polarization state in the ferroelectric layer. Accordingly, each of the gate dielectric layers 150 may include a ferroelectric layer, which may be referred to as an information storage layer. The ferroelectric layer, which may be the information storage layer, may include an Hf-based compound, a Zr-based compound, and/or an Hf—Zr-based compound. For example, the Hf-based compound may be a HfO-based ferroelectric material, the Zr-based compound may include a ZrO-based ferroelectric material, and the Hf—Zr-based compound may include a hafnium zirconium oxide (HZO)-based ferroelectric material. The ferroelectric layer, which may be the information storage layer, may include a ferroelectric material doped with an impurity, for example, at least one of C, Si, Mg, Al, Y, N, Ge, Sn, Gd, La, Sc, and Sr. For example, the ferroelectric layer, which may be the information storage layer, may be a material obtained by doping at least one of HfO₂, ZrO₂, and HZrO with at least one of C, Si, Mg, Al, Y, N, Ge, Sn, Gd, La, Sc, and Sr.

In the gate dielectric layers 150, the information storage layer is not limited to the above-described material types, and may include a material capable of storing information.

The gate capping layers 154 may extend in the Y-direction between adjacent word lines 152, and may be spaced apart from each other in the X-direction. The gate capping layer 154 may be disposed on the word lines 152, and may extend to a space between the word lines 152. For example, the gate capping layer 154 may cover side surfaces and upper surfaces of the word lines 152. The gate capping layer 154 may also be in contact with the upper surface of the horizontal portion 150a of the gate dielectric layer 150.

The gate capping layer 154 may include silicon oxide, silicon nitride, silicon oxynitride, silicon carbonitride, a low-κ dielectric, or combinations thereof. The gate capping layer 154 may include a single layer or a plurality of layers.

The second insulating structure 135 may be disposed between the bit line structure 110 and the gate dielectric layer 150. A lower surface and an upper surface of the second insulating structure 135 may be in contact with an upper surface of the third conductive pattern 110c and a lower surface of the gate dielectric layer 150 of the bit line structure 110, respectively. The second insulating structure 135 may also be disposed between active patterns 140, adjacent to each other in the X-direction. Side surfaces of the second insulating structure 135 may be in contact with the active patterns 140. In an example embodiment, the lower surface of the second insulating structure 135 may be positioned on a level, higher than that of lower surfaces of the active patterns 140.

In an example embodiment, the second insulating structure 135 may include second liners L2 and a second stopper layer S2. The second liners L2 may be disposed on opposite side surfaces of the second stopper layer S2. For example, the second liners L2 may cover the side surfaces of the second stopper layer S2 and side surfaces of the active patterns 140, respectively. The second liners L2 and the second stopper layer S2 may be in contact with the horizontal portion 150a of the gate dielectric layer 150. Upper surfaces and lower surfaces of the second liners L2 may be respectively coplanar with an upper surface and a lower surface of the second stopper layer S2, but the present inventive concept is not limited thereto. In an example embodiment, the lower surfaces of the second liners L2 and the second stopper layer S2 may be disposed on a level, higher than that of a lower surface of the active pattern 140. It is illustrated that an upper surface and a lower surface of the second insulating structure 135 are respectively positioned on levels, the same as those of upper and lower surfaces of the first insulating structure 130, but the present invention is not limited thereto. In some example embodiments, the upper surface of the second insulating structure 135 may be disposed on a level, different from that of the upper surface of the first insulating structure 130, or the lower surface of the second insulating structure 135 may be disposed on a level, different from that of the lower surface of the first insulating structure 130, relative to the upper surface of the lower insulating layer 101.

The second liners L2 may include at least one of silicon oxide, silicon oxynitride, and silicon oxycarbide. The second stopper layer S2 may include silicon oxide.

In an example embodiment, the active pattern 140 may include a first portion 140a and a second portion 140b on the first portion 140a. The first portion 140a may be disposed between the first insulating structure 130 and the second insulating structure 135, and side surfaces of the first portion 140a may be in contact with the first insulating structure 130 and the second insulating structure 135. For example, a first side surface of the first portion 140a may be in contact with the first liner L1 of the first insulating structure 130, and a second side surface, opposite to the first side surface, of the first portion 140a may be in contact with the second liner L2 of the second insulating structure 135.

The second portion 140b of the active pattern 140 may be disposed between the back gate dielectric layer 120 and the gate dielectric layer 150, and side surfaces of the second portion 140b may be in contact with the back gate dielectric layer 120 and the gate dielectric layer 150. In an example embodiment, when lower surfaces of the first insulating structure 130 and the second insulating structure 135 are disposed on a level, higher than that of a lower surface of the active pattern 140, the active pattern 140 may further include a third portion 140c disposed below the first portion 140a, relative to the upper surface of the lower insulating layer 101. Side surfaces and a lower surface of the third portion 140c may be in contact with the third conductive pattern 110c of the bit line structure 110.

The contact patterns 160 may be disposed on the active patterns 140, and may be electrically connected to the active patterns 140. The contact patterns 160 may electrically connect the active patterns 140 and the information storage structure 170 to each other. Lower surfaces of the contact patterns 160 may be in contact with the back gate dielectric layer 120, the active pattern 140, and the gate dielectric layer 150.

The contact patterns 160 may include a conductive material, for example, doped single crystal silicon, doped polycrystalline silicon, a metal, a conductive metal nitride, a metal-semiconductor compound, a conductive metal oxide, conductive graphene, carbon nanotubes, or combinations thereof. In an example embodiment, the contact patterns 160 may include first to fourth contact layers 160a, 160b, 160c, and 160d, sequentially stacked in the vertical direction. For example, the first contact layer 160a may include undoped polycrystalline silicon, the second contact layer 160b may include doped polycrystalline silicon, the third contact layer 160c may include a silicide material, and the fourth contact layer 160d may include a metal. However, depending on example embodiments, the number of layers of the contact patterns 160 and a type of material of the layers may be changed in various manners.

The semiconductor device 100 may further include insulating patterns 165, disposed between the contact patterns 160. Each of the insulating patterns 165 may vertically extend to be in contact with the insulating structure 160 or the back gate capping layer 124. The insulating patterns 165 may spatially separate the contact patterns 160 from each other, and may electrically insulate the contact patterns 160 from each other.

The information storage structures 170 may include first electrodes 172 electrically connected to the contact patterns 160, second electrodes 176 covering the first electrodes 172, and a dielectric layer 174 between the first electrodes 172 and the second electrodes 176.

In an example embodiment, the information storage structures 170 may be capacitors storing information in the DRAM. For example, the dielectric layer 174 of the information storage structures 170 may be a capacitor dielectric layer of the DRAM, and the dielectric layer 174 may include a high-κ dielectric, silicon oxide, silicon nitride, silicon oxynitride, or combinations thereof.

Depending on example embodiments, the information storage structures 170 may be structures that store DRAM and other memory information. For example, the dielectric layer 174 of the information storage structures 170 may be a capacitor dielectric layer of a ferroelectric memory (FeRAM). In this case, the dielectric layer 174 may be a ferroelectric layer capable of recording data using a polarization state. In another embodiment, the dielectric layer 174 may also include a lower dielectric layer including at least one of silicon oxide or a high-κ dielectric, and a ferroelectric layer disposed on the lower dielectric layer.

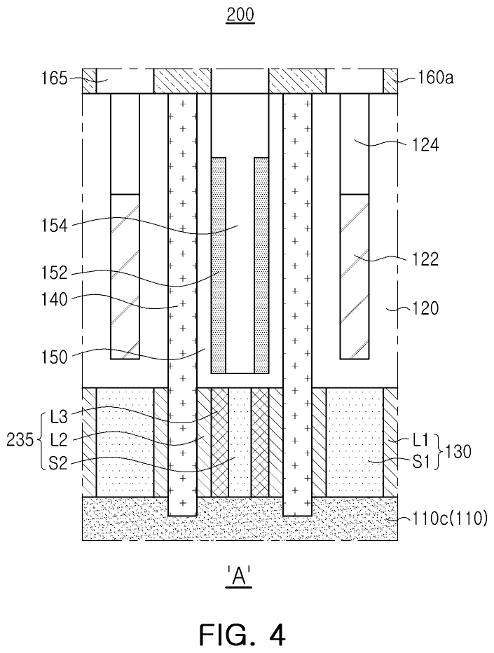

FIGS. 4 to 9 are schematic vertical cross-sectional views of semiconductor devices according to example embodiments.

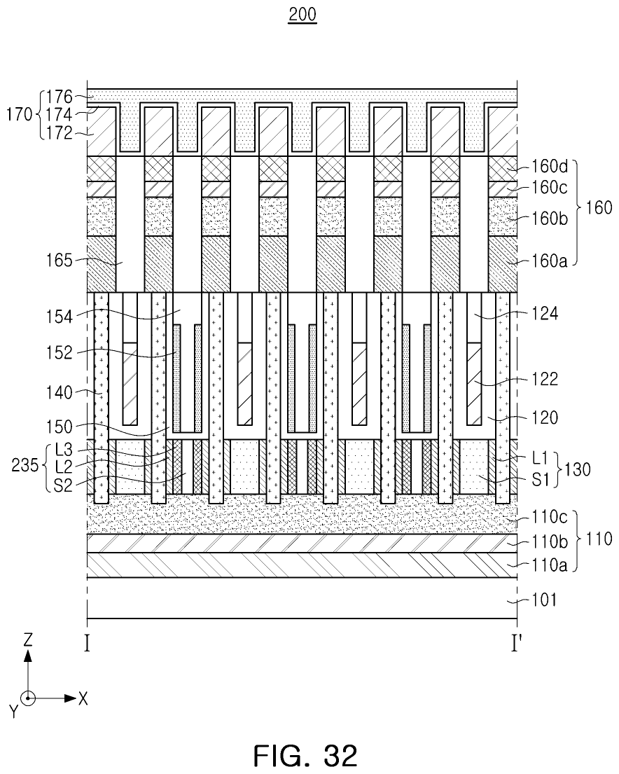

FIG. 4 may correspond to a partially enlarged view of a semiconductor device 200 illustrated in FIG. 32.

Referring to FIG. 4, the semiconductor device 200 may include a first insulating structure 130 disposed between a back gate dielectric layer 120 and a bit line structure 110, and a second insulating structure 235 disposed between a gate dielectric layer 150 and the bit line structure 110. In an example embodiment, the second insulating structure 235 may include a second stopper S2, a second liner L2, and a third liner L3. The third liner L3 may be disposed between the second stopper S2 and the second liner L2, and may be in contact with the gate dielectric layer 150 and the bit line structure 110. The third liner L3 may include a material different from that of the second liner L2. For example, the second liner L2 may include at least one of silicon oxide, silicon oxynitride, and silicon oxycarbide. The third liner L3 may include silicon nitride.

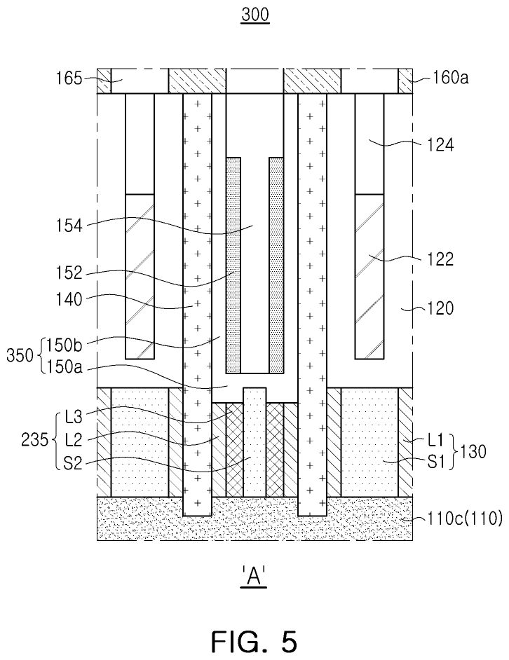

Referring to FIG. 5, a semiconductor device 300 may include a first insulating structure 130 disposed between a back gate dielectric layer 120 and a bit line structure 110, and a second insulating structure 235 disposed between a gate dielectric layer 350 and the bit line structure 110. In an example embodiment, an upper end of a second stopper S2 of the second insulating structure 235 may be disposed on a level higher than those of upper ends of a second liner L2 and a third liner L3, relative to an upper surface of the bit line structure 110 as a reference layer. A horizontal portion 150a of the gate dielectric layer 350 may include a recess, such that the upper end of the second stopper S2 protrudes upwardly in a vertical direction toward the recess of the horizontal portion 150a of the gate dielectric layer 350.

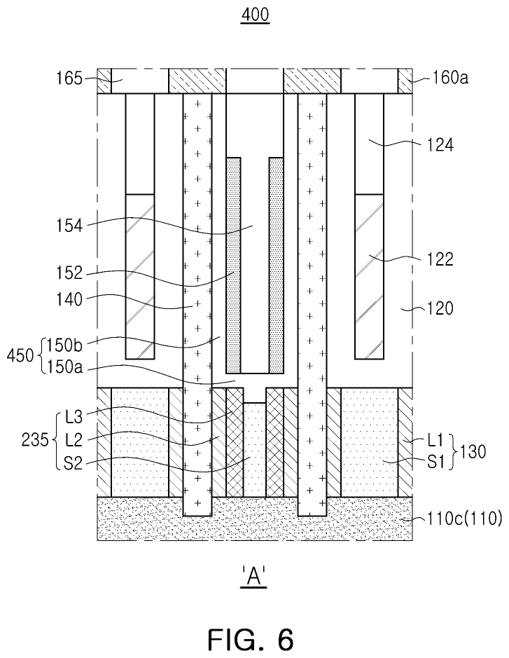

Referring to FIG. 6, the semiconductor device 400 may include a first insulating structure 130 disposed between the back gate dielectric layer 120 and the bit line structure 110, and a second insulating structure 235 disposed between a gate dielectric layer 450 and the bit line structure 110. In an example embodiment, the top of the second stopper S2 of the second insulating structure 235 may be disposed on a level lower than that of the tops of the second liner L2 and the third liner L3, relative to an upper surface of the bit line structure 110. The horizontal portion 150a of the gate dielectric layer 450 may include a protrusion that protrudes vertically downward toward the second stopper S2.

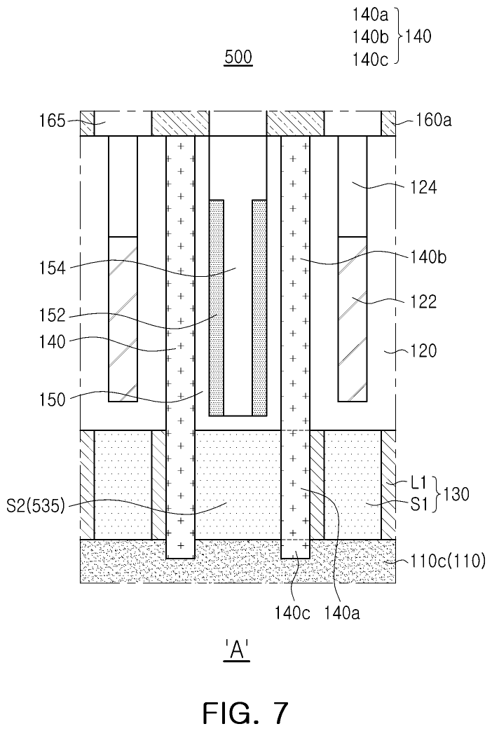

The example embodiments of FIGS. 4 to 6 may also be applied to the example embodiments of FIGS. 7 to 9 described below.

Referring to FIG. 7, a semiconductor device 500 may include a first insulating structure 130 disposed between a back gate dielectric layer 120 and a bit line structure 110, and a second insulating structure 535 disposed between a gate dielectric layer 150 and the bit line structure 110. In an example embodiment, unlike the example embodiment of FIG. 3, a second liner L2 may be omitted from the second insulating structure 535. For example, the second insulating structure 535 may include a second stopper S2, and the second stopper S2 may be in contact with side surfaces of an active pattern 140.

The active pattern 140 may include a first portion 140a, a second portion 140b on the first portion 140a, and a third portion 140c below the first portion 140a. In an example embodiment, the first portion 140a of the active pattern 140 may include a first side surface facing the first insulating structure 130, and a second side surface opposite to the first side surface, the second side surface facing the second insulating structure 535. The first side surface of the first portion 140a may be in contact with a first liner L1, and the second side surface of the first portion 140a may be in contact with the second stopper S2.

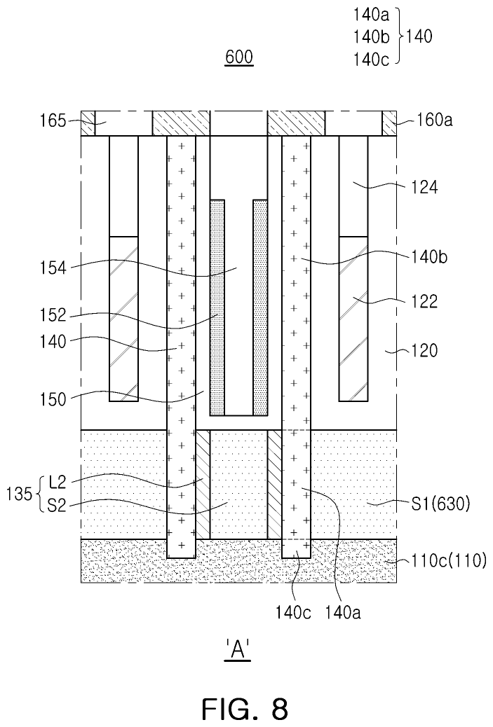

Referring to FIG. 8, a semiconductor device 600 may include a first insulating structure 630 disposed between a back gate dielectric layer 120 and a bit line structure 110, and a second insulating structure 135 disposed between a gate dielectric layer 150 and the bit line structure 110. In an example embodiment, unlike the example embodiment of FIG. 3, a first liner L1 may be omitted from the first insulating structure 630. For example, the first insulating structure 630 may include a first stopper S1, and the first stopper S1 may be in contact with side surfaces of an active pattern 140.

The active pattern 140 may include a first portion 140a, a second portion 140b, and a third portion 140c. In an example embodiment, the first portion 140a of the active pattern 140 may include a first side surface and a second side surface facing the first insulating structure 630 and the second insulating structure 135, respectively. The first side surface of the first portion 140a may be in contact with the first stopper S1, and the second side surface of the first portion 140a may be in contact with a second liner L2.

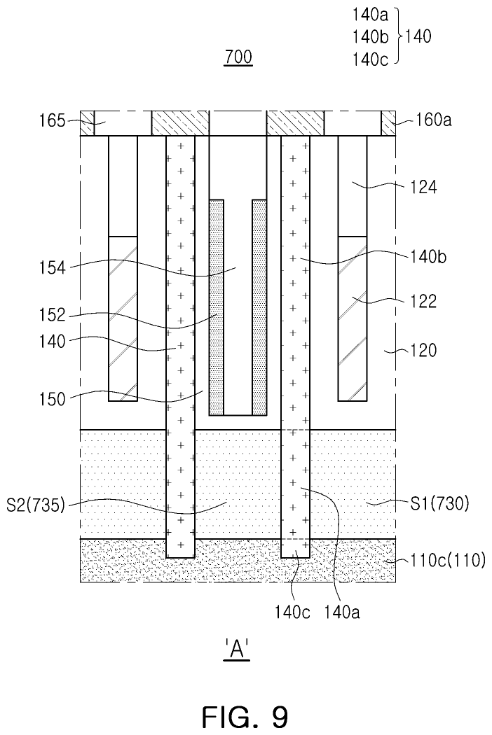

Referring to FIG. 9, a semiconductor device 700 may include a first insulating structure 730 disposed between a back gate dielectric layer 120 and a bit line structure 110, and a second insulating structure 735 disposed between a gate dielectric layer 150 and the bit line structure 110. In an example embodiment, unlike the example embodiment of FIG. 3, a first liner L1 may be omitted from the first insulating structure 730, and a second liner L2 may be omitted from the second insulating structure 735. For example, the first insulating structure 730 may include a first stopper S1, and the first stopper S1 may be in contact with side surfaces of an active pattern 140. The second insulating structure 735 may include a second stopper S2, and the second stopper S2 may be in contact with the side surfaces of the active pattern 140.

The active pattern 140 may include a first portion 140a, a second portion 140b, and a third portion 140c. In an example embodiment, the first portion 140a of the active pattern 140 may include a first side surface and a second side surface facing the first insulating structure 730 and the second insulating structure 735, respectively. The first side surface of the first portion 140a may be in contact with the first stopper S1, and the second side surface of the first portion 140a may be in contact with the second stopper S2.

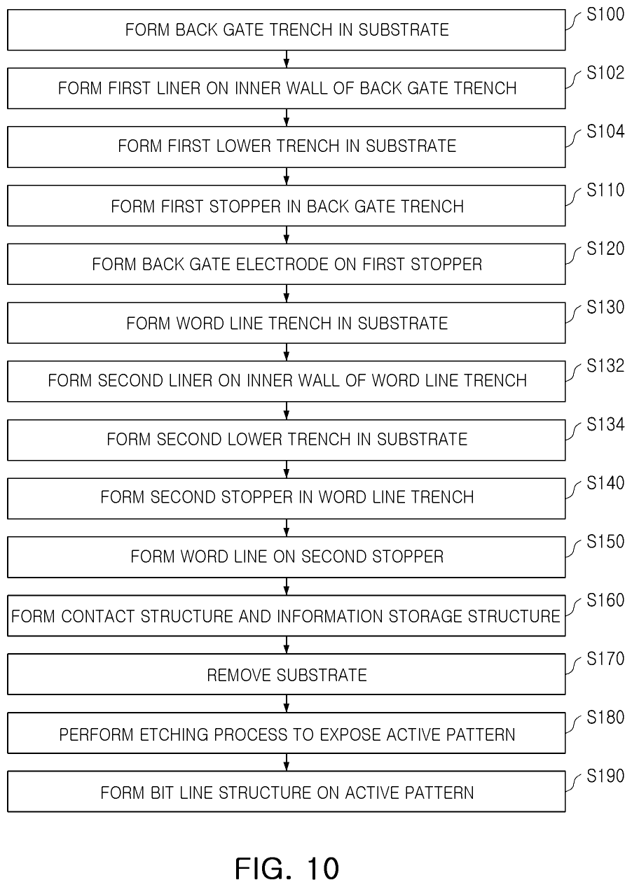

FIG. 10 is a flowchart of a method for manufacturing a semiconductor device according to an example embodiment.

Referring to FIG. 10, a method of manufacturing a semiconductor device according to an example embodiment may include forming a back gate trench in a substrate (S100), forming a first stopper in the back gate trench (S110), forming a back gate electrode on the first stopper (S120), forming a word line trench in the substrate (S130), forming a second stopper in the word line trench (S140), forming a word line on the second stopper (S150), forming a contact structure and an information storage structure on the word line (S160), removing the substrate (S170), performing an etching process to expose an active pattern (S180), and forming a bit line structure on the active pattern (S190). The term “expose” (or “exposed,” or like terms) may be used herein to describe relationships between elements and/or with reference to intermediate processes in fabricating an integrated circuit device, but may not require exposure of a particular element in the completed device. Likewise, the term “not exposed” may be used to describe relationships between elements and/or with reference to intermediate processes in fabricating an integrated circuit device, but may not require a particular clement to be unexposed in the completed device.

In an example embodiment, the method may further include forming a first liner on an inner wall of the back gate trench (S102) after forming the back gate trench in the substrate (S100) and before forming the first stopper in the back gate trench (S110), and forming a first lower trench in the substrate (S104). In an example embodiment, the method may further include forming a second liner on an inner wall of the word line trench (S132) after forming the word line trench in the substrate (S130) and before forming the second stopper in the word line trench (S140), and forming a second lower trench in the substrate (S134).

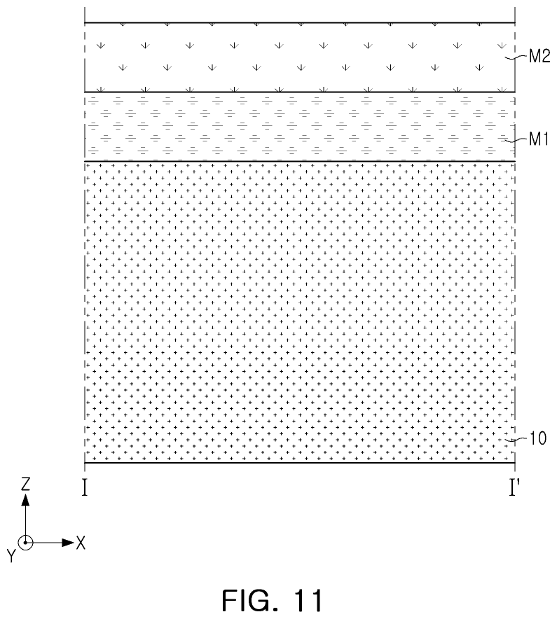

FIGS. 11 to 25 are schematic vertical cross-sectional views of sequential intermediate processes in a method of manufacturing a semiconductor device according to an example embodiment.

Referring to FIG. 11, a first mask layer M1 and a second mask layer M2 may be formed on a substrate 10. The substrate 10 may include single crystal silicon. In an example embodiment, the substrate 10 may be a bulk silicon substrate. The first mask layer M1 and the second mask layer M2 may include at least one of silicon oxide, silicon nitride, and silicon oxynitride. For example, the first mask layer M1 may include silicon nitride, and the second mask layer M2 may include silicon oxide.

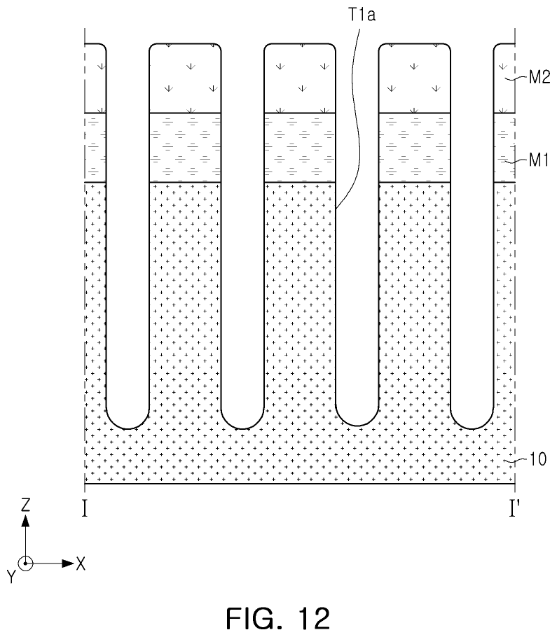

Referring to FIG. 12, a back gate trench T1a may be formed in the substrate 10 by anisotropically etching the substrate 10 (S100). The back gate trench T1a may vertically pass through the first mask layer M1 and the second mask layer M2, and may expose the substrate 10. The back gate trenches T1a may extend in a Y-direction, and may be spaced apart from each other in an X-direction.

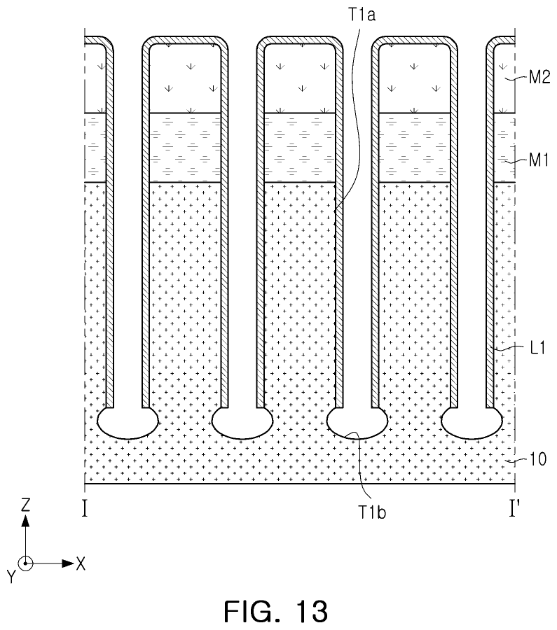

Referring to FIG. 13, a first liner L1 may be formed on an inner wall of the back gate trench T1a (S102), and a first lower trench T1b may be formed in the substrate 10 (S104). First, the first liner L1 may be conformally formed along the inner walls of the back gate trenches T1a. The first liner L1 may cover the inner walls of the back gate trenches T1a, side surfaces of the first mask layer M1, and side surfaces and an upper surface of the second mask layer M2.

The substrate 10 may be exposed in the back gate trenches T1a by anisotropically etching the first liner L1. The exposed substrate 10 may be etched to form the first lower trench T1b. The first lower trench T1b may be formed by wet etching the exposed substrate 10. In cross-sectional view, the first lower trench T1b may have a circular or oval shape. The first lower trench T1b may be formed below the back gate trench T1a, and may be connected to the back gate trench T1a. The first lower trench T1b may extend in the Y-direction along the back gate trench T1a. When the first lower trench T1b is formed, a portion of the substrate 10, covered by the first liner L1, may not be etched.

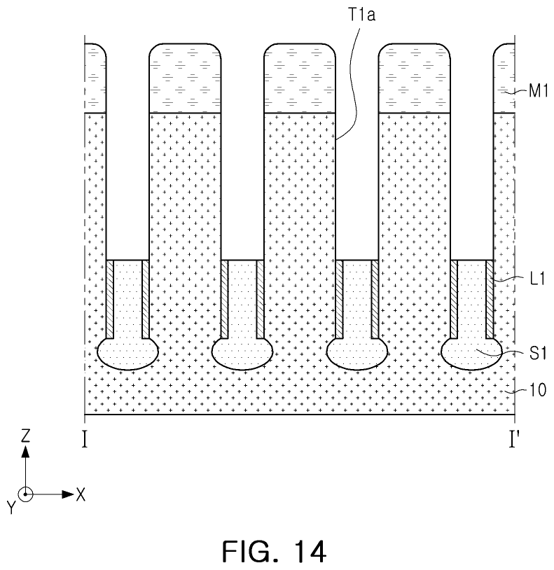

Referring to FIG. 14, a first stopper S1 may be formed in the back gate trench T1a (S110). The first stopper S1 may fill the lower portion of the back gate trench T1a. The term “fill” (or “filling,” or like terms), as may be used herein, is intended to refer broadly to either completely filling a defined space (e.g., the lower portion of the back gate trench T1a) or partially filling the defined space; that is, the defined space need not be entirely filled but may, for example, be partially filled or have voids or other spaces throughout. In an example embodiment, the first stopper S1 may also fill the first lower trench T1b. The first stopper S1 may extend in the Y-direction along the back gate trench T1a and the first lower trench T1b. In an example embodiment, a stopper material layer may be formed to fill the back gate trench T1a and the first lower trench T1b and cover the second mask layer M2, and then the stopper material layer may be etched back to form the first stopper S1. In an example embodiment, the first stopper S1 may be formed by stacking the stopper material layer from a lower surface of the first lower trench T1b without performing an etch-back process.

After the first stopper S1 is formed, the first liner L1 may be etched back to expose the substrate 10 through the back gate trench T1a. It is illustrated that an upper surface of the etched-back first liner L1 and an upper surface of the first stopper S1 are coplanar with each other, but the present inventive concept is not limited thereto. In some example embodiments, the upper surface of the first liner L1 and the upper surface of the first stopper S1 may be disposed on different levels. The second mask layer M2 may be removed.

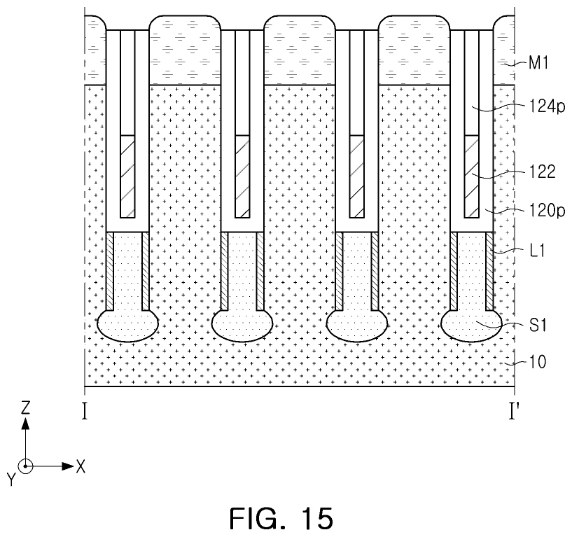

Referring to FIG. 15, the back gate electrode 122 may be formed on the first stopper S1 (S120). First, a dielectric material layer 120p may be conformally formed in an upper portion of the back gate trench T1a, above the lower portion. The dielectric material layer 120p may cover the inner wall of the back gate trench T1a, the upper surface of the first liner L1, and the upper surface of the first stopper S1.

After a conductive material is formed on the dielectric material layer 120p, the back gate electrode 122 may be formed by etching back the conductive material. An insulating material may be formed on the back gate electrode 122 to fill an inner wall of the dielectric material layer 120p and cover the first mask layer M1, and then the insulating material may be etched back to form a preliminary capping layer 124p. In an example embodiment, the back gate electrode 122 may include metal nitride, such as TiN, or polycrystalline silicon.

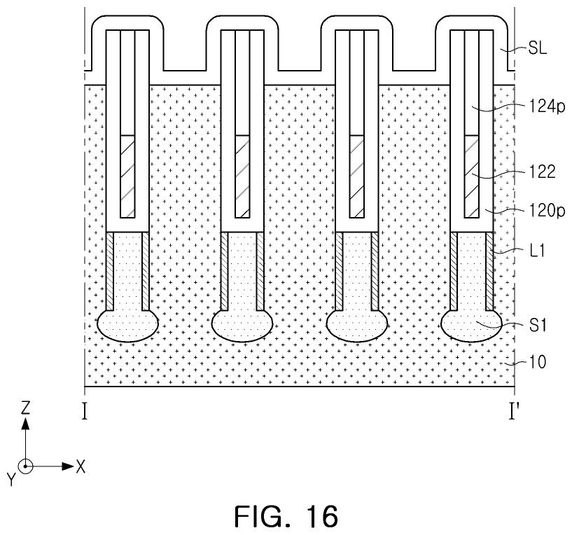

Referring to FIG. 16, an upper surface of the substrate 10 may be exposed by removing the first mask layer M1. For example, the first mask layer M1 may be selectively removed using a wet etching process. A sacrificial material layer SL may be conformally formed to cover the upper surface of the substrate 10, side surfaces of the dielectric material layer 120p, and an upper surface of the preliminary capping layer 124p. The sacrificial material layer SL may include at least one of silicon oxide, silicon nitride, and silicon oxynitride.

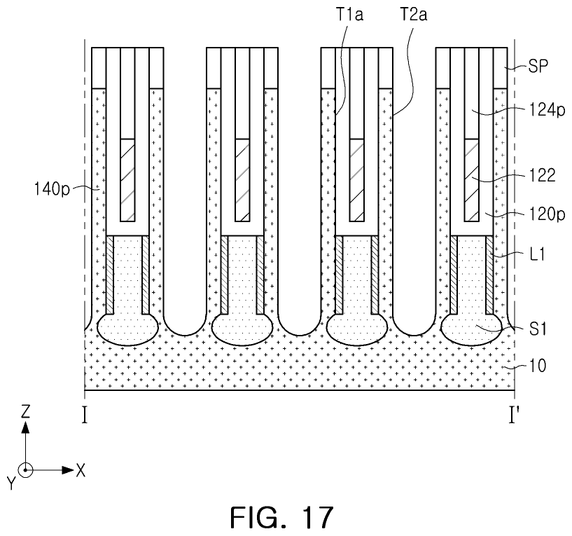

Referring to FIG. 17, a word line trench T2a may be formed in the substrate 10 (S130). The word line trench T2a may be formed by anisotropically etching the sacrificial material layer SL and the substrate 10. The sacrificial material layer SL may be etched to form a sacrificial spacer SP on the side surfaces of the dielectric material layer 120p. The word line trench T2a may expose the substrate 10. The back gate trenches T1a may extend in the Y-direction, and may be spaced apart from each other in the X-direction.

A preliminary active pattern 140p may be formed using an anisotropic etching process. The preliminary active pattern 140p may extend in a vertical direction, and may be defined by the back gate trench T1a and the word line trench T2a. For example, the back gate trench T1a and the word line trench T2a may define side surfaces of the preliminary active pattern 140p. An upper surface of the preliminary active pattern 140p may be covered with the sacrificial spacer SP.

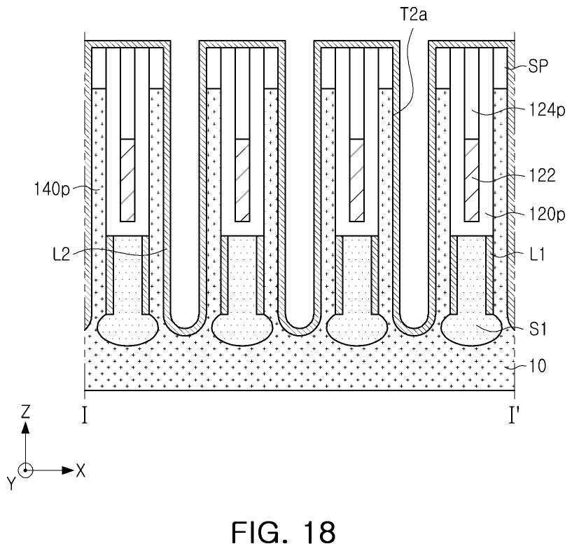

Referring to FIG. 18, a second liner L2 may be formed on an inner wall of the word line trench T2a (S132). The second liner L2 may be conformally formed along the word line trench T2a, the sacrificial spacer SP, the dielectric material layer 120p, and the preliminary capping layer 124p.

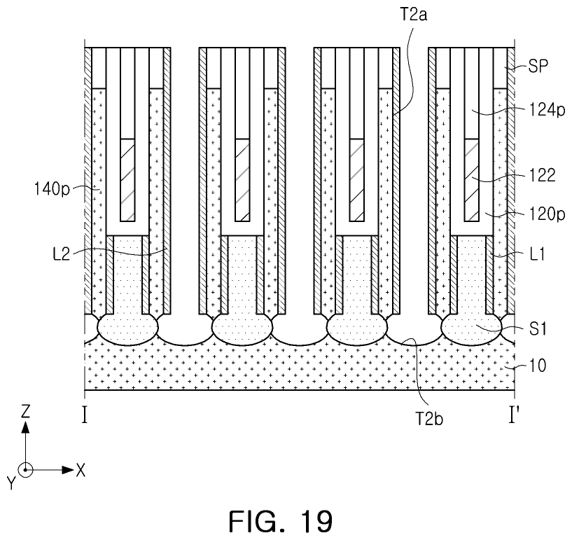

Referring to FIG. 19, a second lower trench T2b may be formed in the substrate 10 (S134). The substrate 10 may be exposed in the word line trench T2a by anisotropically etching the second liner L2. The exposed substrate 10 may be etched to form the second lower trench T2b. The second lower trench T2b may be formed by wet etching the exposed substrate 10. In cross-sectional view, the second lower trench T2b may have a circular or oval shape, and may expose a portion of the first stopper S1. The second lower trench T2b may be formed below the word line trench T2a, and may be connected to the word line trench T2a. The second lower trench T2b may extend in the Y-direction along the word line trench T2a. When the second lower trench T2b is formed, the preliminary active pattern 140p, covered by the second liner L2, may not be etched.

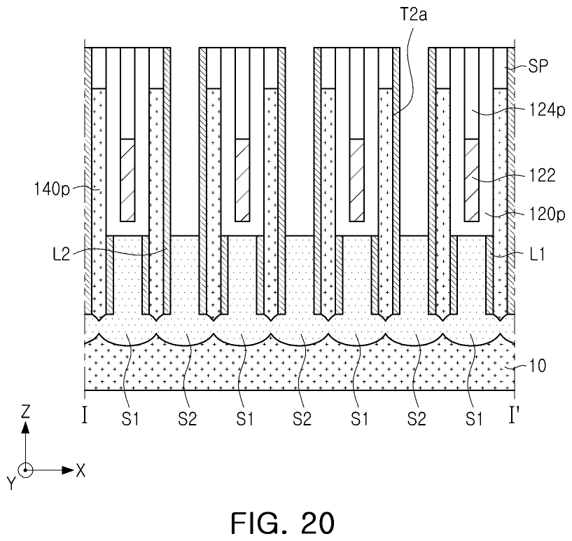

Referring to FIG. 20, a second stopper S2 may be formed in the word line trench T2a (S140). The second stopper S2 may fill the lower portion of the word line trench T2a. In an example embodiment, the second stopper S2 may also fill the second lower trench T2b. The second stopper S2 may extend in the Y-direction along the word line trench T2a and the second lower trench T2b. In an example embodiment, a stopper material layer may be formed to fill the word line trench T2a and the second lower trench T2b and cover the sacrificial spacer SP, dielectric material layer 120p, and the preliminary capping layer 124p, and then the stopper material layer may be etched back to form the second stopper S2. In an example embodiment, the second stopper S2 may be formed by stacking the stopper material layer from a lower surface of the second lower trench T2b without performing an etch-back process.

A portion of the first stopper S1, filling the first lower trench T1b, may be alternately disposed in the X-direction with a portion of the second stopper S2, filling the second lower trench T2b. In an example embodiment, the second stopper S2 may include a material the same as that of the first stopper S1. In an example embodiment, the second stopper S2 may include a material different from that of the first stopper S1.

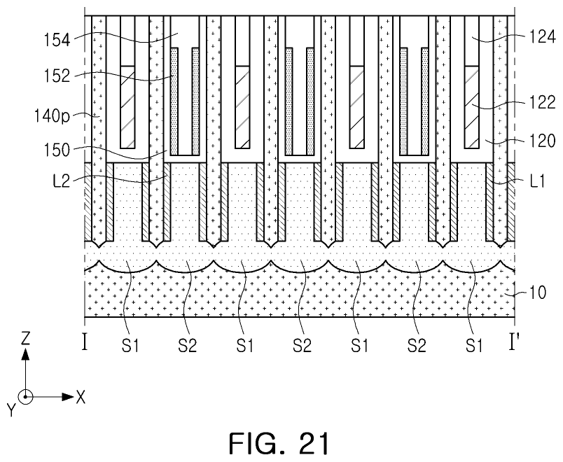

After the second stopper S2 is formed, the second liner L2 may be etched back to expose the preliminary active pattern 140p through the word line trench T2a, as shown in FIG. 21. It is illustrated in FIG. 21 that an upper surface of the etched-back second liner L2 and an upper surface of the second stopper S2 are coplanar with each other, but the present inventive concept is not limited thereto. In some example embodiments, the upper surface of the second liner L2 and the upper surface of the second stopper S2 may be disposed on different levels.

The preliminary active pattern 140p may be spaced apart from the substrate 10. For example, the first stopper S1 and the second stopper S2 may be disposed between the preliminary active pattern 140p and the substrate 10, and a lower surface of the preliminary active pattern 140p may be bonded to the first stopper S1 and the second stopper S2.

Referring to FIG. 21, a word line 152 may be formed on the second stopper S2 (S150). First, a gate dielectric layer 150 may be conformally formed in an upper portion of the word line trench T2a (see FIG. 20), above the lower portion. The gate dielectric layer 150 may cover the inner wall of the word line trench T2a, the upper surface of the second liner L2, and the upper surface of the second stopper S2.

After a conductive material is formed on the gate dielectric layer 150, the word line 152 may be formed by etching back the conductive material. An insulating material may be formed on the word line 152 to fill an inner wall of the gate dielectric layer 150 and cover the dielectric material layer 120p and the preliminary capping layer 124p, and then the insulating material may be etched back to form a gate capping layer 154. In an example embodiment, the word line 152 may be formed by forming a first insulating material on the conductive material and simultaneously etching the conductive material and the first insulating material. The gate capping layer 154 may be formed by depositing a second insulating material on the first insulating material.

After the gate capping layer 154 is formed, the sacrificial spacer SP may be removed. Portions of the dielectric material layer 120p and the preliminary capping layer 124p, positioned on the preliminary active pattern 140p, may be removed to form a back gate dielectric layer 120 and a back gate capping layer 124. Upper surfaces of the back gate dielectric layer 120 and the back gate capping layer 124 may be coplanar (i.e., at a same vertical level relative to a lower surface of the substrate 10) with an upper surface of the preliminary active pattern 140p and an upper surface of the gate capping layer 154.

In an example embodiment, the preliminary active patterns 140p may be patterned in the X-direction before the word line 152 is formed. As illustrated in FIG. 1, the patterned preliminary active patterns 140p may be spaced apart from each other in the X-direction and the Y-direction.

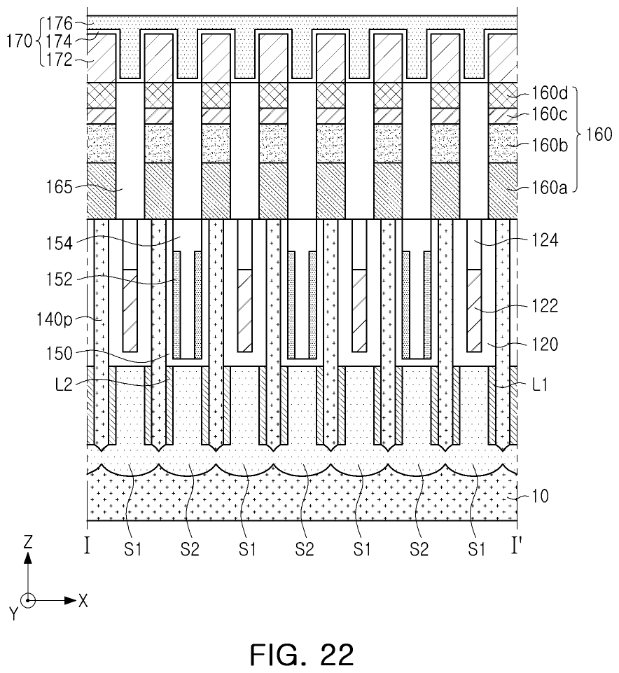

Referring to FIG. 22, a contact structure 160 and an information storage structure 170 may be formed on the word line 152 (S160). The contact structure 160 may be formed by stacking contact material layers and then patterning the contact material layers. The contact structure 160 may include a first contact pattern 160a, a second contact pattern 160b, a third contact pattern 160c, and a fourth contact pattern 160d, sequentially stacked in the vertical direction. The contact structure 160 may be electrically connected to the preliminary active pattern 140p.

Insulating patterns 165 may be formed between the patterned contact structures 160. The insulating patterns 165 may electrically separate the contact structures 160 from each other.

The information storage structure 170, including first electrodes 172, a dielectric layer 174, and a second electrode 176, may be formed on the contact structures 160. The first electrodes 172 may be in contact with fourth contact patterns 160d of the contact structures 160.

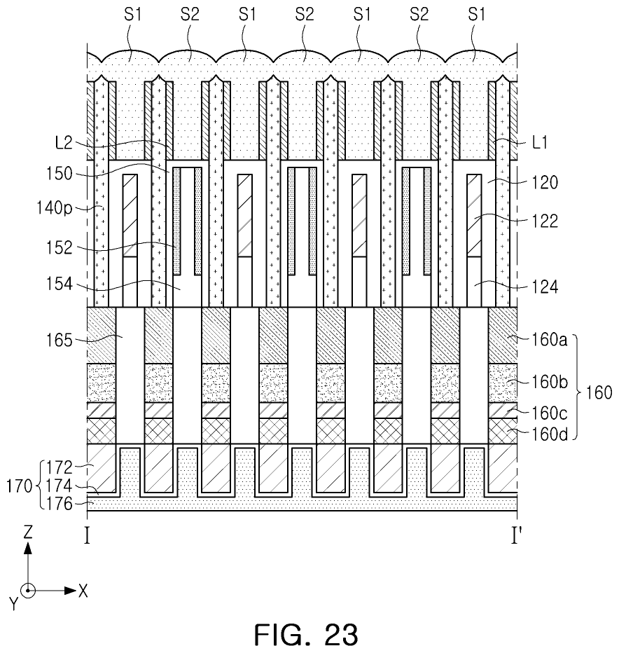

Referring to FIG. 23, a resulting structure of FIG. 22 may be inverted such that the information storage structure 170 is positioned below the substrate 10, and the substrate 10 may be removed using a planarization process (S170). For example, the substrate 10 may be removed using a chemical mechanical polishing (CMP) process. The first stopper S1 and the second stopper S2 may serve as CMP stoppers in the CMP process.

When the first stopper S1 and the second stopper S2 are not present, a metal material of the back gate electrode 122 and the word line 152 may be polished simultaneously with an insulating material such as the back gate dielectric layer 120, the gate dielectric layer 150, and the gate capping layer 154. In this case, dishing or erosion may occur on a surface being polished. However, according to example embodiments of the present inventive concept, the CMP process may be performed in a state in which the first stopper S1 and the second stopper S2, CMP stoppers, are disposed, thereby preventing dishing or corrosion. Accordingly, defects in semiconductor devices may be reduced. In addition, as illustrated in FIG. 11, the substrate 10 may be a bulk silicon substrate rather than a silicon on insulator (SOI) substrate, thereby reducing costs required to manufacture a semiconductor device, as compared to a case in which the SOI substrate is used.

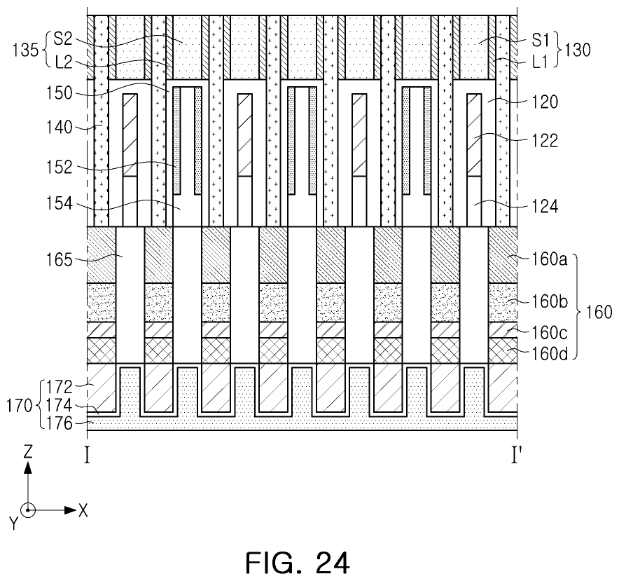

Referring to FIG. 24, an etching process may be performed to expose an active pattern 140 (S180). The etching process may include at least one of an anisotropic etching process, an isotropic etching process, and a CMP process. The preliminary active pattern 140p may be etched to form the active pattern 140 using the etching process, and an upper surface of the active pattern 140 may be exposed.

The first liner L1, the first stopper S1, the second liner L2, and the second stopper S2 may be partially etched using the etching process, and upper surfaces thereof may be coplanar with upper surfaces of the active patterns 140. The etched first liner L1 and first stopper S1 may form a first insulating structure 130, and the etched second liner L2 and second stopper S2 may form a second insulating structure 135.

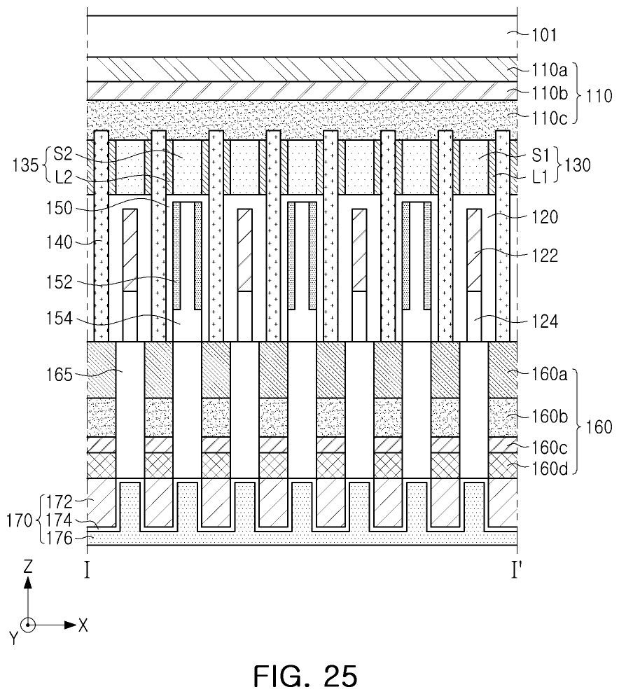

Referring to FIG. 25, a bit line structure 110 may be formed on the active pattern 140 (S190) to manufacture the semiconductor device 100. The bit line structure 110 may include a third conductive pattern 110c, a second conductive pattern 110b, and a first conductive pattern 110a, sequentially stacked on the active patterns 140.

In an example embodiment, a cleaning process may be performed before the bit line structure 110 is formed. The cleaning process may remove an oxide film formed on the active patterns 140. The first liner L1, the first stopper S1, the second liner L2, and the second stopper S2 may be partially etched using the cleaning process, and side surfaces of the active patterns 140 may be exposed.

In an example embodiment, a process of forming a peripheral circuit structure on a lower insulating layer 101 may be further performed. The peripheral circuit structure may include peripheral circuit devices, at least one of the peripheral circuit devices may be electrically connected to the bit line structure 110, and at least one of the peripheral circuit devices may be electrically connected to the information storage structure 170.

In an example embodiment, in the method of manufacturing a semiconductor device illustrated in FIG. 10, forming the first liner L1 on the inner wall of the back gate trench T1a (S102) and forming the first lower trench T1b in the substrate 10 (S104) may be omitted. In this case, as illustrated in FIG. 8, the first insulating structure 630 may not include the first liner L1, and the first stopper S1 may be in contact with the active pattern 140.

In an example embodiment, in the method of manufacturing a semiconductor device illustrated in FIG. 10, forming the second liner L2 on the inner wall of the word line trench T2a (S132) and forming the second lower trench T2b in the substrate 10 (S134) may be omitted. In this case, as illustrated in FIG. 7, the second insulating structure 535 may not include the second liner L2, and the second stopper S2 may be in contact with contact the active pattern 140.

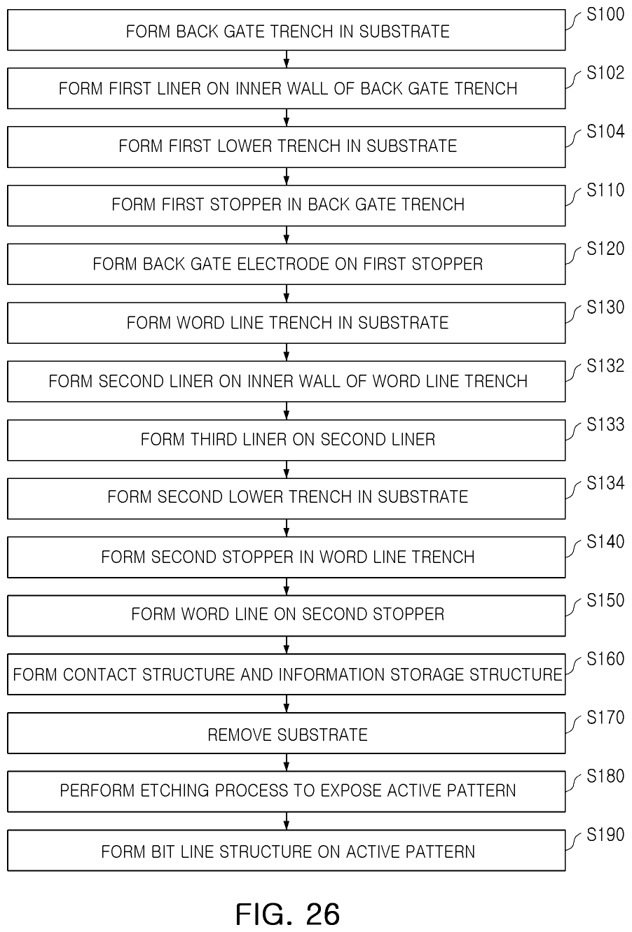

FIG. 26 is a flowchart of a method of manufacturing a semiconductor device according to an example embodiment.

Referring to FIG. 26, as compared to the method of manufacturing a semiconductor device described with reference to FIG. 10, a method of manufacturing a semiconductor device according to an example embodiment may further include forming a third liner L3 on a second liner L2 (S133) after forming the second liner L2 on an inner wall of a word line trench T2a (S132) and before forming a second lower trench T2b in a substrate 10 (S134).

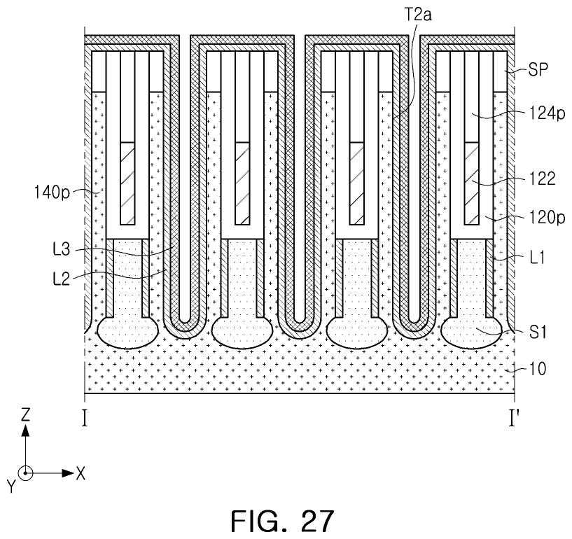

FIGS. 27 to 32 are schematic vertical cross-sectional views of sequential intermediate processes in a method of manufacturing a semiconductor device according to an example embodiment. FIGS. 27 to 32 are diagrams illustrating the method of manufacturing a semiconductor device illustrated in FIG. 26.

Referring to FIG. 27, after a process of forming a second liner L2, described with reference to FIG. 18, is performed, a third liner L3 may be formed on the second liner L2. The third liner L3 may be conformally disposed along a surface of the second liner L2. The third liner L3 may include a material different from that of the second liner L2.

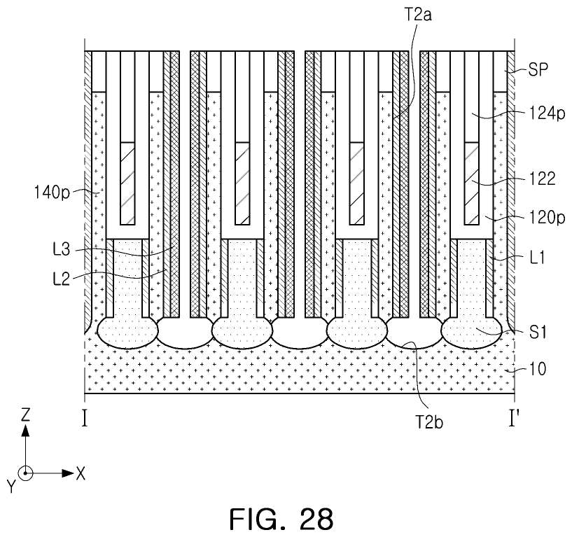

Referring to FIG. 28, a second lower trench T2b may be formed in a substrate 10 (S134). The substrate 10 may be exposed in a word line trench T2a by anisotropically etching the second liner L2 and the third liner L3. The exposed substrate 10 may be etched to form the second lower trench T2b. The second lower trench T2b may be formed by wet etching the exposed substrate 10. When the second lower trench T2b is formed, a preliminary active pattern 140p, covered by the second liner L2, may not be etched.

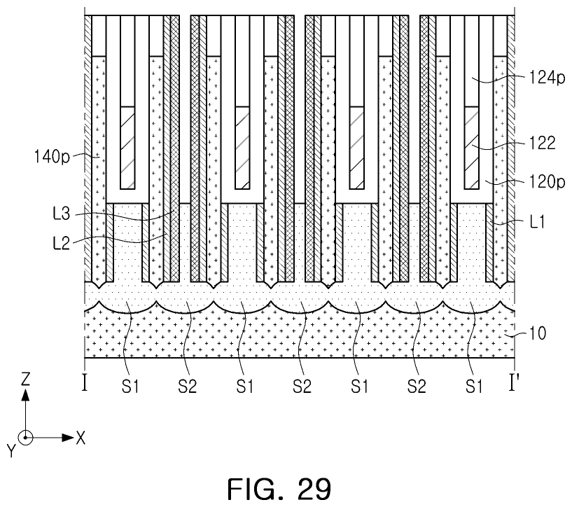

Referring to FIG. 29, a second stopper S2 may be formed in the word line trench T2a (S140). The second stopper S2 may fill a lower portion of the word line trench T2a and the second lower trench T2b. In an example embodiment, a stopper material layer may be formed to fill the word line trench T2a and the second lower trench T2b and cover a sacrificial spacer SP, a dielectric material layer 120p, and a preliminary capping layer 124p, and then the stopper material layer may be etched back to form the second stopper S2. The third liner L3 may protect the second liner L2 and the preliminary active pattern 140p from being etched, when the stopper material layer is etched back.

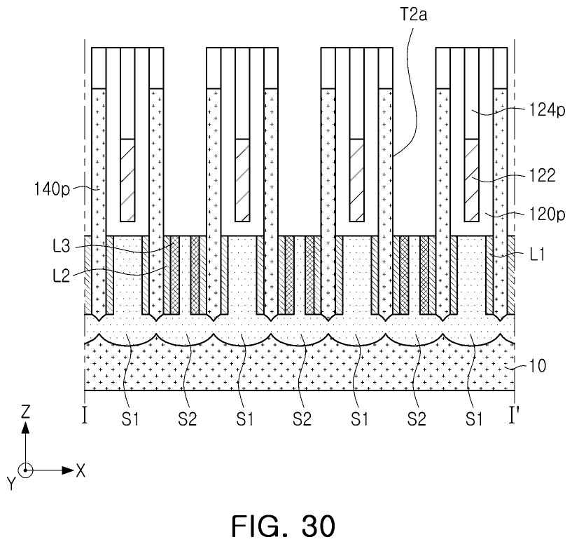

Referring to FIG. 30, after the second stopper S2 is formed, the second liner L2 and the third liner L3 may be etched back to expose the preliminary active pattern 140p by the word line trench T2a. First, the third liner L3 may be etched back using a wet etching process, and the second liner L2 may be exposed. Thereafter, the second liner L2 may be etched back using a wet etching process, and the preliminary active pattern 140p may be exposed.

It is illustrated that an upper surface of the etched-back second liner L2 and an upper surface of the etched-back third liner L3 are coplanar with an upper surface of the second stopper S2, but the present invention is not limited thereto. As illustrated in FIGS. 5 and 6, the upper surface of the second liner L2, the upper surface of the third liner L3, and the upper surface of the second stopper S2 may be disposed on different levels, relative to the upper surface of the substrate 10.

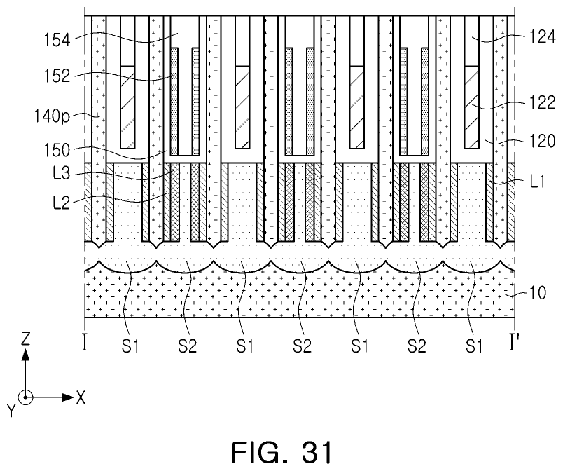

Referring to FIG. 31, a word line 152 may be formed on the second stopper S2 (S150). In addition, a gate dielectric layer 150 and a gate capping layer 154 may be formed.

Referring to FIG. 32, processes of operations S160 to S190, described with reference to FIGS. 22 to 25, may be further performed to manufacture the semiconductor device 200. FIG. 4 may correspond to a partially enlarged view of FIG. 32.

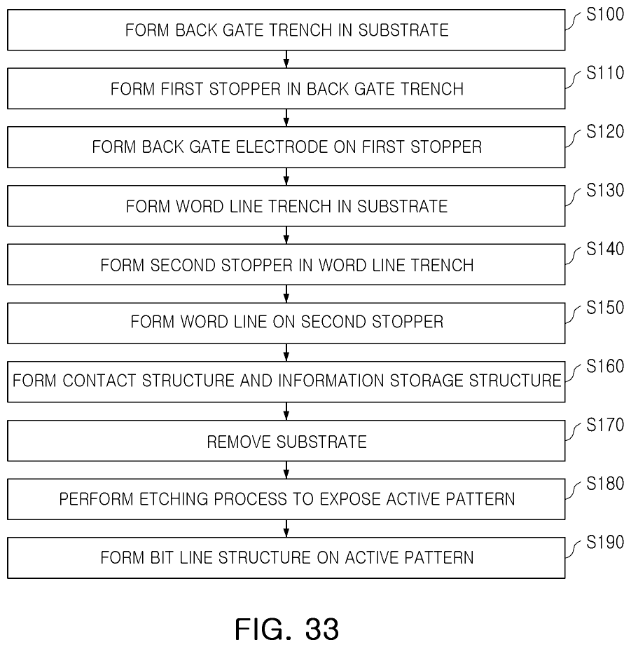

FIG. 33 is a flowchart of a method of manufacturing a semiconductor device according to an example embodiment.

Referring to FIG. 33, as compared to the method of manufacturing a semiconductor device described with reference to FIG. 10, in a method of manufacturing a semiconductor device according to an example embodiment, forming a first liner L1 on an inner wall of a back gate trench T1a (S102), forming a first lower trench T1b in a substrate 10 (S104), forming a second liner L2 on an inner wall of a word line trench T2a (S132), and forming a second lower trench T2b in the substrate 10 (S134) may be omitted.

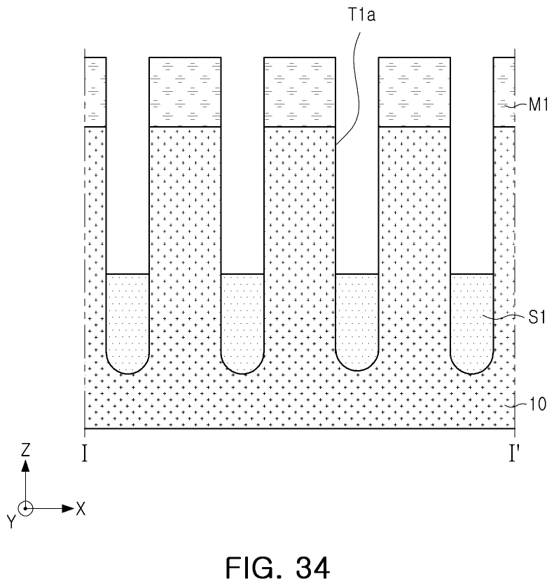

FIGS. 34 to 38 are schematic vertical cross-sectional views of sequential intermediate processes in a method of manufacturing a semiconductor device according to an example embodiment. Specifically, FIGS. 34 to 38 depict intermediate processes in the method of manufacturing a semiconductor device illustrated in the flowchart of FIG. 33.

Referring to FIG. 34, a back gate trench T1a may be formed in a substrate 10 by anisotropically etching the substrate 10 (S100), and a first stopper S1 may be formed in the back gate trench T1a (S110). The first stopper S1 may fill a lower portion of the back gate trench T1a. Unlike FIG. 14, a first lower trench T1b may not be formed below the back gate trench T1a.

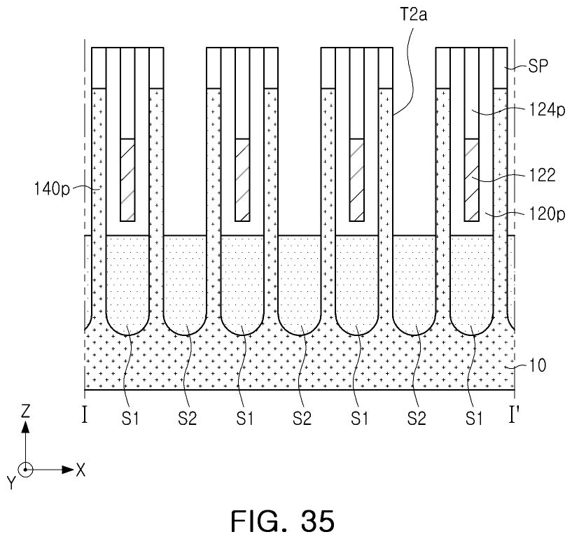

Referring to FIG. 35, processes of operation S120, operation S130, and operation S140 described with reference to FIGS. 15 to 17, FIGS. 19, and FIG. 20 may be performed. A back gate electrode 122 may be formed on the first stopper S1, and a second stopper S2 may be formed in the word line trench T2a. The second stopper S2 may fill a lower portion of the word line trench T2a. Unlike FIG. 20, a second lower trench T2b may not be formed below the word line trench T2a. Preliminary active patterns 140p may be disposed on the substrate 10, and may be spaced apart from each other in an X-direction.

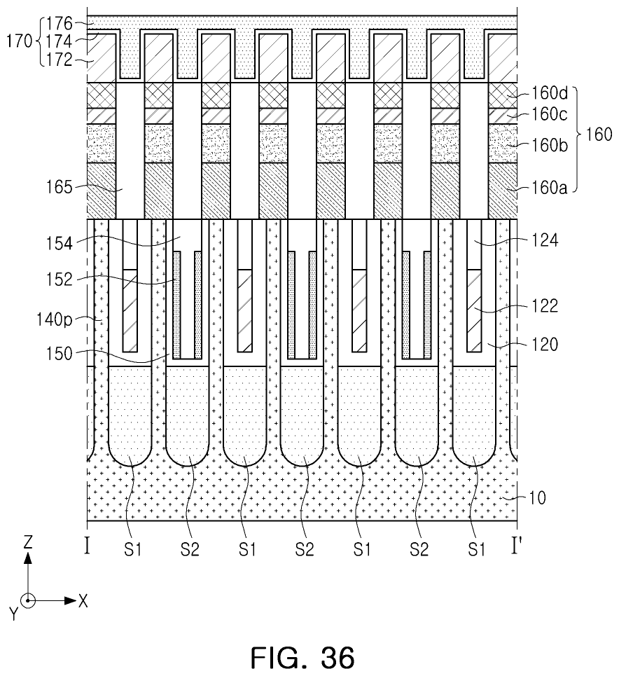

Referring to FIG. 36, processes of operation S150 and operation S160, described with reference to FIGS. 21 and 22, may be performed. A word line 152 may be formed on the second stopper S2, and a contact structure 160 and an information storage structure 170 may be formed on the word line 152.

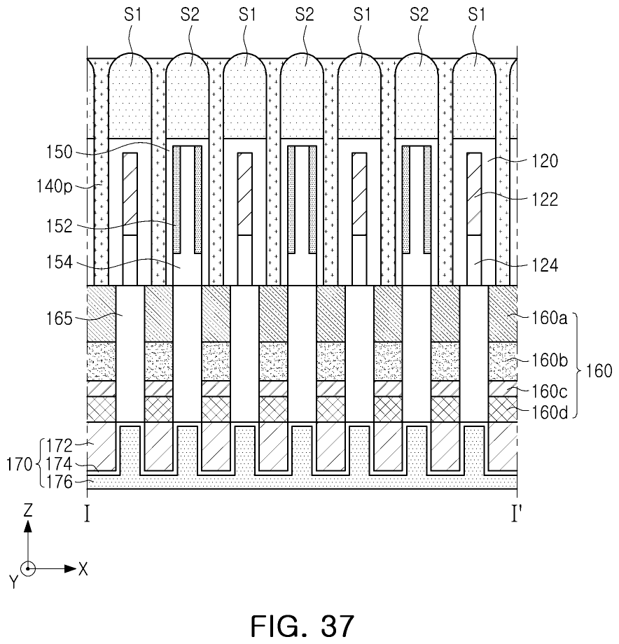

Referring to FIG. 37, a resulting structure of FIG. 36 may be inverted such that the information storage structure 170 is positioned below the substrate 10, and the substrate 10 may be removed using a planarization process (S170). For example, the substrate 10 may be removed using a CMP process. The first stop S1 and the second stop S2 may serve as CMP stoppers in the CMP process.

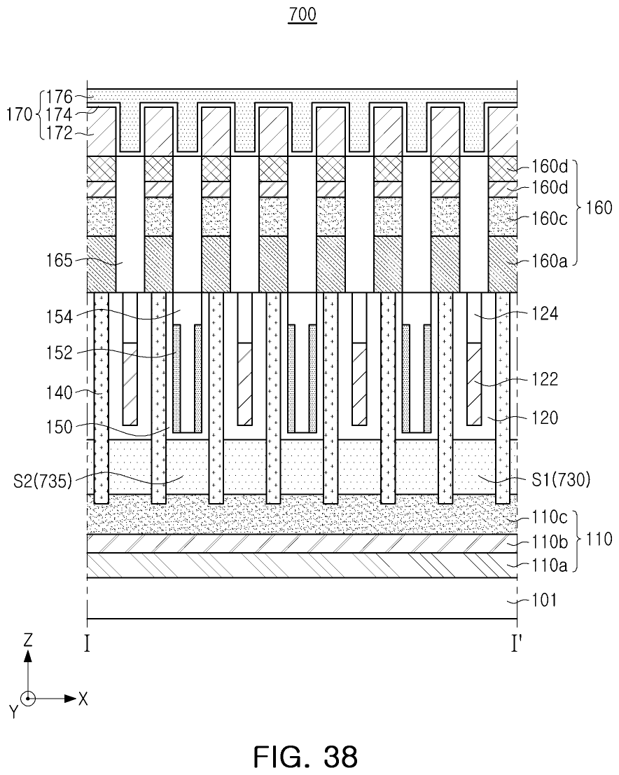

Referring to FIG. 38, an etching process may be performed to expose an active pattern 140 (S180), and a bit line structure 110 may be formed on the active pattern 140 (S190) to manufacture the semiconductor device 700. FIG. 9 may correspond to a partial enlarged view of FIG. 38.

According to example embodiments of the present inventive concept, a first stopper and a second stopper may be disposed below a back gate electrode and a word line, thereby preventing dishing or corrosion during a CMP process. In addition, in a method of manufacturing a semiconductor device according to the present disclosure, an SOI substrate may not be used, thereby reducing costs required to manufacture the semiconductor device.

While example embodiments have been shown and described above, it will be apparent to those skilled in the art that modifications and variations could be made without departing from the scope of the present inventive concept as defined by the appended claims.

What is claimed is:

1. A semiconductor device, comprising:
a bit line structure;
a back gate electrode and a word line on the bit line structure;
an active pattern between the back gate electrode and the word line, on the bit line structure, the active pattern extending in a vertical direction perpendicular to a lower surface of the semiconductor device;
a back gate dielectric layer between the back gate electrode and the active pattern, the back gate dielectric layer on a side surface and a lower surface of the back gate electrode; and
a first insulating structure between the back gate dielectric layer and the bit line structure,
wherein the first insulating structure includes a first stopper in contact with the back gate dielectric layer and the bit line structure, and
the back gate dielectric layer is spaced apart from the bit line structure by the first stopper in the vertical direction.

2. The semiconductor device of claim 1, wherein
the first insulating structure further includes a first liner between the first stopper and the active pattern, and
the first liner is in contact with a side surface of the active pattern.

3. The semiconductor device of claim 1, wherein the first stopper is in contact with a side surface of the active pattern.

4. The semiconductor device of claim 1, wherein the back gate dielectric layer includes a horizontal portion on the lower surface of the back gate electrode, and a vertical portion upwardly extending from the horizontal portion, the vertical portion on the side surface of the back gate electrode.

5. The semiconductor device of claim 4, wherein the horizontal portion of the back gate dielectric layer is in contact with an upper surface of the first insulating structure.

6. The semiconductor device of claim 1, wherein the back gate dielectric layer has a U-shape, in cross-sectional view.

7. The semiconductor device of claim 1, further comprising:
a gate dielectric layer between the word line and the active pattern, the gate dielectric layer on a side surface and a lower surface of the word line, and
a second insulating structure between the gate dielectric layer and the bit line structure, the second insulating structure including a second stopper.

8. The semiconductor device of claim 7, wherein the gate dielectric layer is spaced apart from the bit line structure in the vertical direction.

9. The semiconductor device of claim 7, wherein
the second insulating structure further includes a second liner between the second stopper and the active pattern, and
the second liner is in contact with a side surface of the active pattern.

10. The semiconductor device of claim 9, wherein the second insulating structure further includes a third liner between the second liner and the second stopper.

11. The semiconductor device of claim 10, wherein the third liner includes a material different from that of the second liner.

12. The semiconductor device of claim 9, wherein
the gate dielectric layer includes a horizontal portion on the lower surface of the word line, and
the horizontal portion of the gate dielectric layer includes a protrusion portion extending in the vertical direction toward the second liner.

13. The semiconductor device of claim 7, wherein
the gate dielectric layer includes a horizontal portion on the lower surface of the word line, and
the horizontal portion of the gate dielectric layer includes a protrusion portion extending in the vertical direction toward the second stopper.

14. The semiconductor device of claim 7, wherein the second stopper is in contact with a side surface of the active pattern.

15. A semiconductor device, comprising:
a bit line structure;
a back gate electrode and a word line on the bit line structure;
an active pattern between the back gate electrode and the word line, on the bit line structure, the active pattern extending in a vertical direction perpendicular to a lower surface of the semiconductor device;
a back gate dielectric layer between the back gate electrode and the active pattern, the back gate dielectric layer on a side surface and a lower surface of the back gate electrode;
a gate dielectric layer between the word line and the active pattern, the gate dielectric layer on a side surface and a lower surface of the word line;
a first insulating structure between the back gate dielectric layer and the bit line structure; and
a second insulating structure between the gate dielectric layer and the bit line structure,
wherein the active pattern includes a first portion and a second portion on the first portion,
the first portion of the active pattern is in contact with the first insulating structure and the second insulating structure, and
the second portion of the active pattern is in contact with the back gate dielectric layer and the gate dielectric layer.

16. The semiconductor device of claim 15, wherein
the active pattern further includes a third portion below the second portion, and
a lower surface and a side surface of the third portion of the active pattern are in contact with the bit line structure.

17. The semiconductor device of claim 15, wherein
the first insulating structure includes a first stopper and first liners on opposite sides of the first stopper, and
the second portion of the active pattern is in contact with one of the first liners.

18. The semiconductor device of claim 15, wherein
the second insulating structure includes a second stopper and second liners on opposite sides of the second stopper, and
the second portion of the active pattern is in contact with one of the second liners.

19. The semiconductor device of claim 18, wherein
the second insulating structure further includes third liners between the second stopper and the second liners, and
the second liners include a material different from that of the third liners.

20. A semiconductor device, comprising:
a bit line structure;
a back gate electrode and a word line on the bit line structure;
an active pattern between the back gate electrode and the word line, on the bit line structure, the active pattern extending in a vertical direction perpendicular to a lower surface of the semiconductor device;
a contact structure on the active pattern;
an information storage structure on the contact structure;
a back gate dielectric layer between the back gate electrode and the active pattern, the back gate dielectric layer on a side surface and a lower surface of the back gate electrode, the back gate dielectric layer in contact with a side surface of the active pattern;
a gate dielectric layer between the word line and the active pattern, the gate dielectric layer on a side surface and a lower surface of the word line, the gate dielectric layer in contact with the side surface of the active pattern;
a first insulating structure in contact with a lower surface of the back gate dielectric layer and an upper surface of the bit line structure; and
a second insulating structure in contact with a lower surface of the gate dielectric layer and the upper surface of the bit line structure,
wherein the first insulating structure includes a first stopper in contact with the back gate dielectric layer and the bit line structure, and
the back gate dielectric layer is spaced apart from the bit line structure by the first stopper in the vertical direction.
